(19) United States
(12) Patent Application Publication
(10) Pub. No.: US 2004/0131949 A1
(43) Pub. Date: Jul. 8, 2004

(54) Phase mask for forming diffraction grating, method of fabricating phase mask, and method of forming diffraction grating

(75) Inventors: Masaaki Kurihara, Shinjuku-Ku (JP); Nobuhito Toyama, Shinjuku-Ku (JP)

Correspondence Address: PARKHURST & WENDEL, L.L.P., 1421 PRINCE STREET, SUITE 210, ALEXANDRIA, VA, 22314-2805, US

(73) Assignee: Dai Nippon Printing Co., Ltd., Shinjuku-Ku (JP)

(21) Appl. No.: 10/614,345

(22) Filed: Jul. 8, 2003

(30) Foreign Application Priority Data
Jul. 9, 2002 (JP) 2002-200558

(51) Int. Cl. G03F 9/00; G03C 5/00

(52) U.S. Cl. 430/5; 430/322; 430/323; 430/324

(57) ABSTRACT

A phase mask comprises a transparent substrate having one surface provided with a pattern of a plurality of grooves. A diffraction grating is formed in an object for an optical medium, including a photosensitive part by exposing the object to UV light containing diffracted light rays to cause the refractive index of the photosensitive part of the object to change by interference fringes produced by interference of diffracted light rays of different orders of diffraction. The pattern of the grooves has a duty ratio adjusted according to the positions of the grooves so that apodization exposure can be achieved when the object is exposed to the UV light through the phase mask.

### TECHNICAL FIELD

The present invention relates to a phase mask for forming a diffraction grating on an optical waveguide, such as an optical fiber, a method of fabricating the phase mask, and a method of forming a diffraction grating.

### BACKGROUND ART

Optical fibers have caused a great innovation in global communication and made possible high-quality, large-capacity transoceanic telephone communication. It is a known technique to form a Bragg diffraction grating in an optical fiber by forming an axial refractive index distribution in the core of the optical fiber. The reflectance and the width of wavelength characteristic of the diffraction grating are determined by adjusting the period of diffraction grating and the magnitude of refractive-index modulation to use the diffraction grating as a wavelength division multiplexer for optical communication, as a narrow-band high-reflection mirror for lasers and sensors or as a wavelength-selective filter for filtering laser light rays of undesired wavelengths in a fiber amplifier.

It is preferable to use light having a wavelength of 1.55 82 m for a long-distance communication system to reduce the attenuation of the light in a quartz fiber to a minimum. The grating constant of a diffraction grating of an optical fiber for transmitting light of 1.55 82 m in wavelength must be about 500 nm. It is difficult to form such a fine structure in the core of an optical fiber. A Bragg diffraction grating is formed in the core of an optical fiber by a method including many complicated processes including a side polishing process, a photolithographic process, a holographic exposure process and reactive ion-beam etching process. Thus, the production of optical fibers provided with a Bragg diffraction grating takes much time and a low yield.

A recently developed diffraction grating forming method forms a diffraction grating by directly irradiating an optical fiber with ultraviolet light (UV light) to cause a change in refractive index directly in the core of the optical fiber. This diffraction grating forming method using UV light does not need complicated processes and has become applied practically with the progress of associated techniques.

This known diffraction grating forming method using UV light uses, to form a diffraction grating having a small grating constant of about 500 nm, an interference method using the interference of two light waves, a method that writes one refractive grating plane at one point with a focused single laser light pulse emitted by an excimer laser, or an irradiation method using a phase shift mask (hereinafter, referred to simply as “phase mask”) provided with a grating for irradiating an optical fiber.

In carrying out the interference method using two light waves, there is a problem in the quality of a transverse light beam, namely, spatial coherence. The method that writes one refractive grating plane at one point needs to use a minute step-control technique of submicron accuracy and to form a very narrow light beam and to write many planes, which inevitably requires difficult operations.

Thus, the irradiation method using a phase mask and capable of solving those problems has become deemed to be attractive.

This known irradiation method using a phase mask for forming a diffraction grating in the core of an optical fiber, however, needs to carry out the axial apodization of the core of an optical fiber to modulate refractive index. Thus, the irradiation method needs to carry out two exposure steps, i.e., an exposure step using a phase mask, and an apodization functional exposure step.

A method disclosed in JP7-140311A achieves the same effect by using a phase mask and a spatial amplitude filter disposed in front of the phase mask, and irradiating an optical fiber through the spatial amplitude filter and the phase mask.

This prior art method changes the intensity distribution of an illuminating light beam (UV beam) for illuminating the phase mask in a direction along the length of the grating of the phase mask. The intensity distribution of the illuminating light beam is changed, for example, in a Gaussian distribution.

As mentioned above, the irradiation method that irradiates an optical fiber, i.e., a device for optical communication, through a phase mask to form a diffraction grating in the optical fiber needs to carry out apodization to modulate the refractive index of the optical fiber axially. The irradiation method having the two exposure steps, i.e., the exposure step using the phase mask, and the apodization functional exposure step, is troublesome and the improvement of yield has been desired.

### DISCLOSURE OF THE INVENTION

The present invention has been made in view of the foregoing problems and it is therefore an object of the present invention to provide a phase mask, for forming a diffraction grating, capable of forming a diffraction grating in an optical fiber by a single-exposure method using a phase mask instead of by the method including two exposure steps, i.e., an exposure step using a conventional phase mask and an apodization exposure step, or by the method using the phase mask and the spatial amplitude filter disposed in front of the phase mask, a method of fabricating the phase mask, and a method of forming a diffraction grating.

According to a first aspect of the present invention, a phase mask, for forming a diffraction grating in an object for an optical medium, including a photosensitive part by exposing the object to UV light containing diffracted light rays to cause the refractive index of the photosensitive part of the object to change by interference fringes produced by interference of diffracted light rays of different orders of diffraction, comprises: a transparent substrate having one surface provided with a pattern of a plurality of grooves; wherein the pattern of the grooves has a duty ratio adjusted according to the positions of the grooves so that apodization exposure can be achieved when the object is exposed to the UV light through the phase mask.

In the phase mask according to the present invention, the duty ratio of the pattern is adjusted by adjusting the respective widths of the grooves for apodization exposure according to the positions of the grooves.

According to a second aspect of the present invention, a phase mask, for forming a diffraction grating in an object for an optical medium, including a photosensitive part by exposing the object to UV light containing diffracted light rays to cause the refractive index of the photosensitive part of the object to change by interference fringes produced by interference of diffracted light rays of different orders of diffraction, comprises: a transparent substrate having one surface provided with a pattern of a plurality of grooves; wherein the respective depths of the grooves are adjusted according to the positions of the grooves so that apodization exposure can be achieved when the object is exposed to the UV light through the phase mask.

The phase mask according to the present invention is characterized in forming a diffraction grating in the object having a discontinuously changing period.

In the phase mask according to the present invention, the object is used for forming an optical waveguide.

In the phase mask according to the present invention, the object is used for forming an optical fiber.

According to a third aspect of the present invention, a phase mask fabricating method of fabricating a phase mask, for forming a diffraction grating in an object for an optical medium, including a photosensitive part by exposing the object to UV light containing diffracted light rays to cause the refractive index of the photosensitive part of the object to change by interference fringes produced by interference of diffracted light rays of different orders of diffraction, comprising a transparent substrate having one surface provided with a pattern of a plurality of grooves, comprises the steps of preparing a transparent substrate; and processing the transparent substrate by a photolithographic process including an exposure step for forming grooves, a pattern development step and an etching step; wherein exposure for forming the grooves is changed during the photolithographic process such that the pattern of the grooves has a duty ratio adjusted according to the positions of the grooves so that apodization exposure can be achieved when the object is exposed to UV light through the phase mask.

In the phase mask fabricating method according to the present invention, the photolithographic process adjusts the exposure by a multiple exposure method in forming the grooves.

According to a fourth aspect of the present invention, a phase mask fabricating method of fabricating a phase mask, for forming a diffraction grating in an object forming an optical medium and including a photosensitive part by exposing the object to UV light containing diffracted light rays to cause the refractive index of the photosensitive part of the object to change by interference fringes produced by interference of diffracted light rays of different orders of diffraction, comprising a transparent substrate having one surface provided with a pattern of a plurality of grooves, comprises the steps of: preparing a transparent substrate; and processing the transparent substrate by a photolithographic process including an exposure step for forming grooves, a pattern development step and an etching step; wherein the number of times of the photolithographic process in order to adjust the respective depths of the grooves according to the positions of the grooves so that apodization exposure can be achieved when the object is exposed to the UV light through the phase mask.

In the phase mask fabricating method according to the present invention, the exposure step in the photolithographic process is carried out by an electron lithography system or a laser lithography system.

In the phase mask fabricating method according to the present invention, the object is used for forming an optical guide.

In the phase mask fabricating method according to the present invention, the object is used for forming an optical fiber.

According to a fifth aspect of the present invention, a diffraction grating forming method using a phase mask having a transparent substrate having one surface provided with a pattern of a plurality of grooves having a duty ratio adjusted according to the positions of the grooves so that apodization exposure can be achieved when an object for an optical medium, having a photosensitive part is exposed to UV light through the phase mask, comprises the steps of: exposing the object to UV light containing diffracted light rays diffracted by the phase mask; and forming a diffraction grating in the object by causing the refractive index of the photosensitive part of the object to change by interference fringes produced by interference of the diffracted light rays of different orders of diffraction.

According to a sixth aspect of the present invention, a diffraction grating forming method using a phase mask having a transparent substrate having one surface provided with a pattern of a plurality of grooves respectively having depths adjusted according to the positions of the grooves so that apodization exposure can be achieved when an object for an optical medium, having a photosensitive part is exposed to the UV light through the phase mask comprises the steps of: exposing the object to UV light containing diffracted light rays diffracted by the phase mask; and forming a diffraction grating in the object by causing the refractive index of the photosensitive part of the object to change by interference fringes produced by interference of the diffracted light rays of different orders of diffraction.

The term “duty ratio” used herein is the ratio of the width of the grooves to that of ridges between the grooves.

The optical intensity of the influence of zero-order light on the optical fiber can be reduced by adjusting the duty ratio.

Generally, the effect of the duty ration on reducing the influence of zero-order light is the greatest when the duty ratio is one and the effect decreases as the duty ratio changes from one.

The effect of adjustment of the depth of the grooves according to the coordinates of the diffraction grating is equal to the effect on reducing the influence of zero-order light by the adjustment of the duty ratio. The adjustment of the depth of the grooves suppresses side lobes in a reflection spectrum.

The phase mask of the present invention, to be used by a diffraction grating forming method of forming a diffraction grating in an optical fiber, i.e., a device for optical communication, is capable of forming a satisfactory diffraction grating in an optical fiber by a single-exposure method instead of by a double-exposure method including an exposure step using a phase mask and an apodization exposure step, or by the exposure method using a phase mask and a spatial amplitude filter disposed in front of the phase mask as shown in FIG. 3 of JP7-140311A. The phase mask of the present invention enables achieving diffraction grating formation and apodization by a single exposure step.

The diffraction grating forming method of the present invention can be carried out by a conventional exposure system and does not need a complicated exposure system that is needed by the method disclosed in JP7-140311A.

In forming a diffraction grating in an optical fiber, the grooves are adjusted to change UV light diffracting efficiency so that the characteristic of the reflection spectrum of the diffraction grating is satisfactory. A diffraction grating can be formed only by a single exposure step instead of by two exposure steps, and the optical fiber can be processed for apodization. Thus, a diffraction grating can efficiently be formed in an optical fiber.

Naturally, the phase mask of the present invention for forming a diffraction grating can be applied to forming a diffraction grating in which the period changes discontinuously.

The effect of the phase mask fabricating method according to the present invention of fabricating a phase mask for forming a diffraction grating, having a single exposure step is equal to that of the conventional method of forming a diffraction grating in an optical device, i.e., a device for optical communication, comprising two exposure steps, i.e., an exposure step using the conventional phase mask and an apodization exposure step.

The effect of the diffraction grating forming method according to the present invention having a single exposure step using the phase mask is equal to that of the conventional diffraction grating forming method comprising two exposure steps, i.e., an exposure step using the conventional phase mask and an apodization exposure step.

Thus, the present invention is capable of efficiently forming a diffraction grating in an optical fiber.

### BRIEF DESCRIPTION OF THE DRAWINGS

FIG. 1A is a sectional view of a phase mask in a first embodiment according to the present invention for forming a diffraction grating;

FIG. 1B is a graph showing the relation between the duty ratio of a pattern and position;

FIGS. 2A to 2I are sectional views of a workpiece in successive steps of a phase mask fabricating method of fabricating the phase mask in the first embodiment shown in FIG. 1A;

FIG. 3A is a sectional view of a phase mask in a second embodiment according to the present invention for forming a diffraction grating;

FIG. 3B is a graph showing the relation between the depth of grooves formed in a pattern and position;

FIGS. 4A to 4H are sectional views of a workpiece in successive steps of a phase mask fabricating method of fabricating the phase mask in the second embodiment shown in FIG. 3A; and

FIGS. 5A to 5C are views of assistance in explaining a method of processing an optical fiber and a phase mask to be used by the method.

### BEST MODE FOR CARRYING OUT THE INVENTION

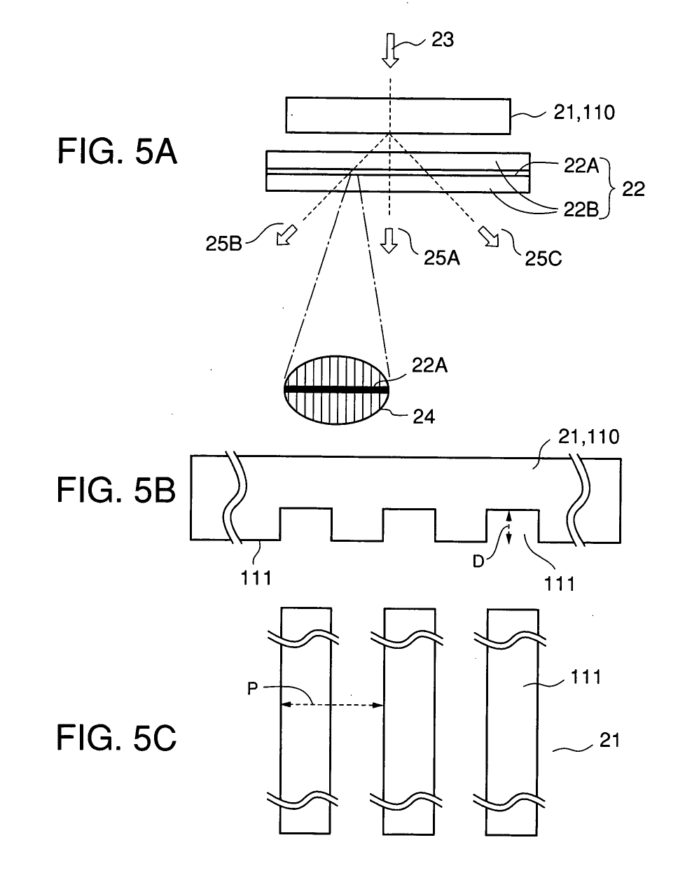

Preferred embodiments of the present invention will be described in connection with the accompanying drawings. A diffraction grating forming method of forming a diffraction grating in an optical fiber using a phase mask will be explained with reference to FIGS. 5A and 5B.

Referring to FIG. 5A, A phase mask 21 has a quartz substrate having one surface provided with grooves 111 of a predetermined depth arranged at predetermined pitches. A diffraction grating is formed in a core 22A of an optical fiber 22 by irradiating the optical fiber 22 through the phase mask 21 with a laser beam of 248 nm in wavelength emitted by a KrF excimer laser to change the refractive index of the core 22A surrounded by a portion 22B of the optical fiber 22.

FIG. 5A is an enlarged typical view to facilitate understanding a pattern of interference fringes 24 formed in the core 22A (solid part), and FIGS. 5B and 5C are a sectional view of the phase mask 21 and a plan view of the grooves 111, respectively. In FIGS. 5A to 5C, D and P indicates the depth and the pitch, respectively, of the grooves 111.

The depth of the grooves 111 is selectively determined so as to change by a change corresponding to the phase π rad of the laser beam emitted by the KrF excimer laser. A zero-order beam 25A is substantially intercepted by the phase mask 21, and principal light beams that can travel through the phase mask 21 are a diverging plus first-order diffracted light beam 25B and a diverging minus first-order diffracted light beam 25C.

Therefore, the core 22A of the optical fiber 22 is irradiated with the plus first-order diffracted light beam 25B or the minus first-order diffracted light beam 25C to form a diffraction grating 24 by causing a change in the refractive index of the optical fiber 2 at this pitch P.

Phase masks embodying the present invention for forming a diffraction grating will be explained.

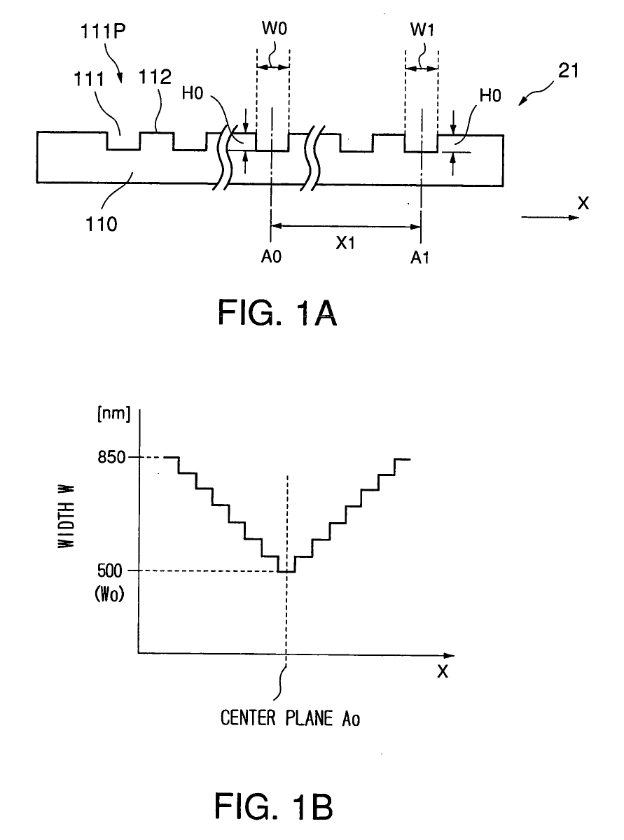

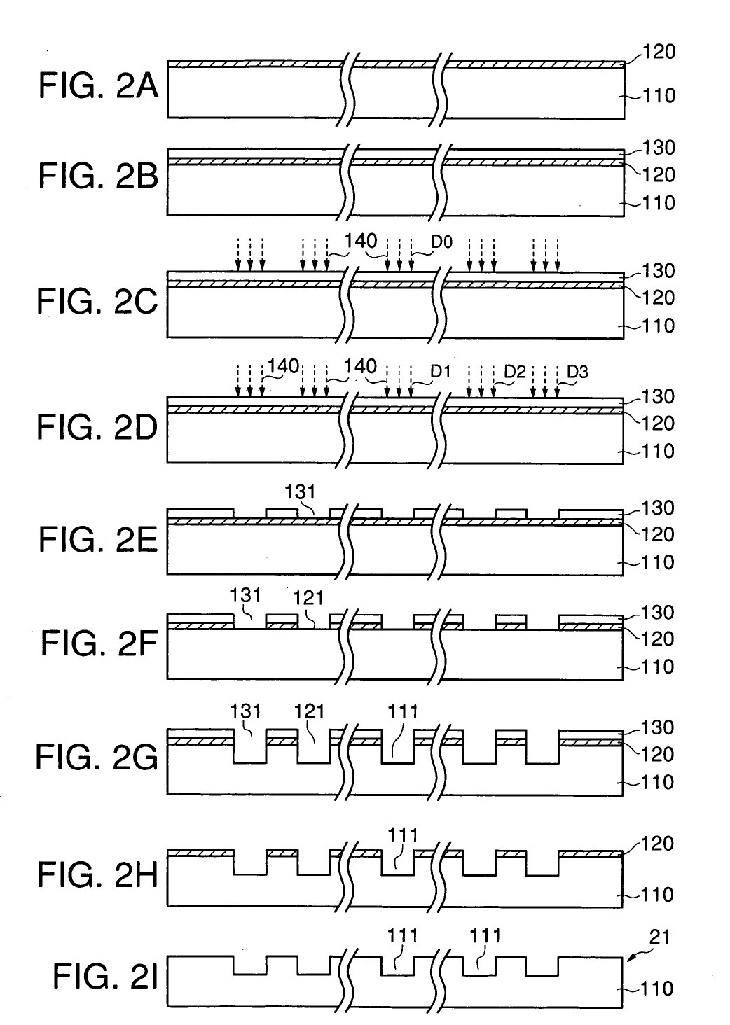

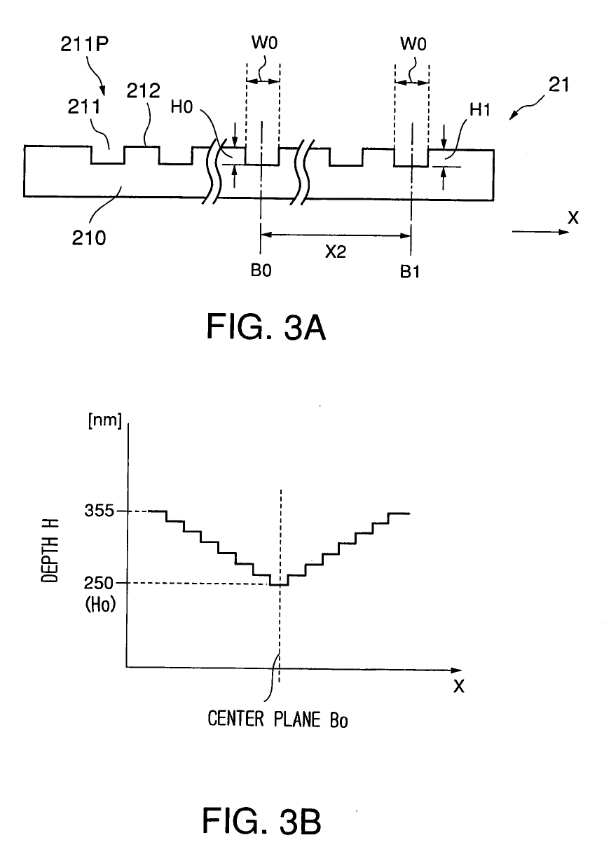

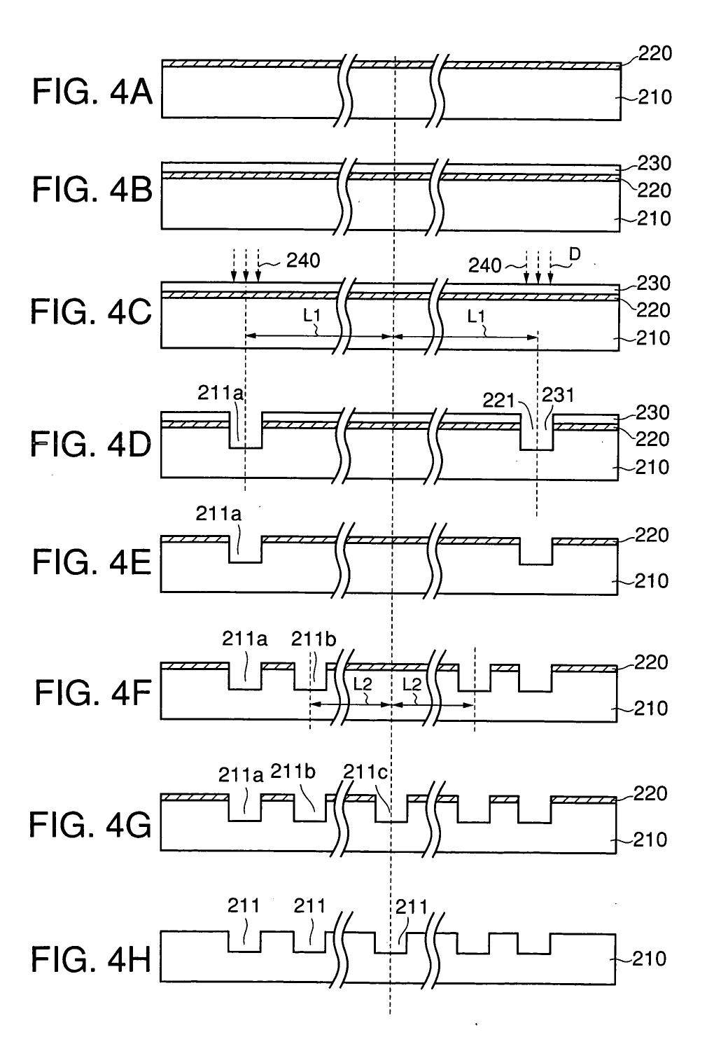

FIG. 1A is a sectional view of a phase mask in a first embodiment according to the present invention for forming a diffraction grating, FIG. 1B is a graph showing the relation between the duty ratio of a pattern and position with respect to the direction of the arrow X, FIGS. 2A to 2I are sectional views of a workpiece in successive steps of a phase mask fabricating method of fabricating the phase mask in the first embodiment shown in FIG. 1A, FIG. 3A is a sectional view of a phase mask in a second embodiment according to the present invention for forming a diffraction grating, FIG. 3B is a graph showing the relation between the depth of grooves formed in a pattern and position with respect to the direction of the arrow X, and FIGS. 4A to 4H are sectional views of a workpiece in successive steps of a phase mask fabricating method of fabricating the phase mask in the second embodiment shown in FIG. 3A.

The direction of the arrow X is perpendicular to the length of the grooves formed in a pattern.

Shown in FIGS. 1A to 3B are a transparent substrate (quartz substrate) 110, grooves 111, ridges 112, a screening film (chromium film) 120, openings 121 formed in the screening film 120, a resist film 130, openings 131 formed in the resist film 130, an electron beam 140, a transparent substrate (quartz substrate) 210, grooves 211, 211a, 211b and 211c formed in the transparent substrate 210, ridges 212, a screening film (chromium film) 220, openings 221 formed in the screening film 220, a resist film 230, openings 231 formed in the resist film 230, and an electron beam 240.

The phase mask 21 in the first embodiment for forming a diffraction grating will be described with reference to FIG. 1A.

The phase mask 21 has the transparent substrate 110 having one surface provided with a pattern 111P of the plurality of grooves 111. An object for forming an optical medium is irradiated with diffracted UV rays diffracted by the pattern 111P of the grooves 111. The refractive index of the photosensitive part of the object is changed by the agency of interference fringes produced by the interference of diffracted UV rays of different orders. The duty ratio of the pattern 111P is adjusted according to the coordinates of the diffraction grating so that an apodization exposure step can be achieved simultaneously with an exposure step using the phase mask 21 in forming the diffraction grating.

A photolithographic process for forming the grooves 111 includes a series of steps for exposure, pattern development and etching. In the photolithographic process, an exposure amount (exposure) is adjusted according to the coordinates of the diffraction grating to adjust the duty ratio of the pattern 111P according to the coordinates of the diffraction grating.

For example, the grooves 111 have eight stepped widths W and the same depth Ho as shown in FIG. 1B. In FIG. 1A, the groove 111 having a width of Wo in a center position Ao, and a groove 111 having a width of W₁ in a position Al at a distance X₁ from the center position Ao are shown.

A phase mask fabricating method of fabricating the phase mask in the first embodiment will be described with reference to FIGS. 2A to 2I.

Referring to FIGS. 2A to 2I, in the photolithographic process, for forming the grooves 111, including the series of steps for exposure, pattern development and etching, an electron lithography system adjusts the exposure for forming the grooves 111 according to the coordinates of the diffraction grating by multiple exposure. The exposure may be adjusted by any suitable means other than the multiple exposures.

The transparent substrate 110 is prepared. The transparent substrate 110 is transparent to light to be used for exposure to form the diffraction grating 24 in the optical fiber 22. The screening film 120 of chromium or the like resistant to etching (dry etching) for forming the grooves 111 in the transparent substrate 110 is formed on one of the surfaces of the transparent substrate 110 as shown in FIG. 2A. Then, the screening film 120 is coated with a positive resist film 130 sensitive to an electron beam as shown in FIG. 2B.

Subsequently, a first exposure step is performed to expose parts of the resist film 130 corresponding to the grooves 111 in a predetermined exposure (exposure dose) DO as shown in FIG. 2C.

Then, as shown in FIG. 2D, a second exposure step that exposes the parts of the resist film 130 corresponding to the grooves 111 in an exposure P₁ once to several times according to the positions of those parts on the X-axis perpendicular to the length of the grooves 111 to expose those parts of the resist film 130 in different total exposures, respectively.

The exposures for the positions on the X-axis are determined empirically or through simulation.

Then, the exposed resist film 130 is subjected to a developing step to form the openings 131 in parts of the resist film 130 corresponding to the grooves 111, as shown in FIG. 2E. The widths of the openings 131 are dependent on the exposures in which the parts of the resist film 130 corresponding to the grooves 111, are exposed.

Parts of the screening film 120 exposed in the openings 131 of the resist film 130 are removed by an etching step to form openings 121 as shown in FIG. 2F.

Generally, the etching step is a dry etching process using a chlorine-containing etching gas.

Then, the transparent substrate 110 is subjected to a dry etching step using the screening film 120 and a fluorine-containing etching gas to form the grooves 111 in a predetermined depth as shown in FIG. 2G.

Then, the resist film 130 is removed (FIG. 2H) and the screening film 120 is removed to complete the phase mask 21 as shown in FIG. 2I.

The phase mask 21 in the first embodiment is thus fabricated.

The phase mask 21 in the second embodiment for forming a diffraction grating will be described with reference to FIGS. 3A and 3B.

The phase mask 21 has the transparent substrate 210 having one surface provided with a pattern 211P of the plurality of grooves 211. An object for an optical medium is irradiated with diffracted UV rays diffracted by the pattern 211P of the grooves 211. The refractive index of the photosensitive part of the object is changed by the agency of interference fringes produced by the interference of diffracted UV rays of different orders. The depths of the grooves 211 are adjusted according to the coordinates of the diffraction grating so that an apodization exposure step can be achieved simultaneously with an exposure step using the phase mask 21 in forming the diffraction grating.

A photolithographic process for forming the grooves 211 includes a series of steps for exposure, pattern development and etching. In the photolithographic process, parts of the surface of the transparent substrate 110 are etched in different depths according to the coordinates of the grooves 211.

For example, the grooves 211 have eight stepped depths H and the same width Wo as shown in FIG. 3B.

In FIG. 3A, the groove 211 having a depth of Ho in a center position Bo, and a groove 211 having a depth of H₁ in a position B₁ at a distance X₂ from the center position Bo are shown.

A phase mask fabricating method of fabricating the phase mask in the second embodiment will be described with reference to FIGS. 4A to 4H.

The photolithographic process for forming the grooves 211 including the series of steps for exposure, pattern development and etching is repeated several cycles. In the photolithographic process, parts of the surface of the transparent substrate 110 are etched in different depths according to the coordinates of a diffraction grating to adjust the depths of the grooves 211 according to the coordinates of the diffraction grating.

The depths of the grooves 211 may be determined so as to be distributed according to the coordinates of the diffraction grating by any other suitable method.

First, the grooves 211 in positions at a distance L1 from the center plane Bo are formed.

The phase mask fabricating method shown in FIGS. 4A to 4H is similar to that shown in FIGS. 2A to 2I. The transparent substrate 110 transparent to light to be used for exposure to form the diffraction grating 24 in the optical fiber 22 is prepared, the screening film 220 of chromium or the like resistant to etching (dry etching) for forming the grooves 211 in the transparent substrate 210 is formed on one of the surfaces of the transparent substrate 210 as shown in FIG. 4A. Then, the screening film 220 is coated with a positive resist film 230 sensitive to an electron beam as shown in FIG. 4B.

Subsequently, an exposure step is performed to expose parts of the resist film 130 corresponding to the grooves 211 at the distance L1 from the center position Bo, in a predetermined exposure (exposure dose) D as shown in FIG. 4C.

Then, as shown in FIG. 4D, the exposed resist film 230 is subjected to a developing step to form the openings 231 in parts of the resist film 230 corresponding to the grooves 211a, and parts of the screening film 220 exposed in the openings 231 of the resist film 230 are removed by etching. Then, the transparent substrate 210 is subjected to a dry etching step using the screening film 220 as a mask and fluorine-containing etching gas to form the grooves 211a in a predetermined depth.

Then, the resist film 220 is removed (FIG. 4E).

Thus, the grooves 211a are formed in the parts of the transparent substrate 210 at the distance L1 on the X-axis from the center plane Bo.

Similarly, the grooves 211b are formed in parts of the transparent substrate 210 at a distance L2 on the X-axis from the center Position Bo. The foregoing phase mask fabricating method is repeated to form the rest of the grooves 211 in predetermined parts of the transparent substrate 210 as shown in FIGS. 4F to 4H.

After all the grooves 211a, 211b and 211c have been formed, the screening film 220 is removed to complete the phase mask 21 in the second embodiment shown in FIG. 3 (FIG. 4H).

The phase mask in the second embodiment is thus fabricated.

### EXAMPLES

A phase mask in an example is the same as the phase mask in the first embodiment fabricated by the phase mask fabricating method previously described in connection with FIGS. 2A to 2I.

Grooves 111 of 10 mm in length are formed in a transparent substrate 110 of quartz at pitches of 1.06 μm in a pattern 111P corresponding to the pattern of a diffraction grating.

The phase mask in the example will be described with reference to FIGS. 1A, 1B and 2A-2H.

A screening film 120 of chromium or the like having a thickness of 110 Å was formed on one of the surfaces of the transparent substrate 110 as shown in FIG. 2A. Then, a 500 nm thick positive resist film 130 sensitive to an electron beam (SEP7000 commercially available from Hitachi Zeon) was formed on the screening film 120 and dried as shown in FIG. 2B.

Subsequently, a first exposure step was performed using an electron lithography system (MEBESIII commercially available from Applied Material) to expose parts of the resist film 130 corresponding to the grooves 111 in a predetermined exposure (exposure dose) of 4 μC/cm² as shown in FIG. 2C.

Then, as shown in FIG. 2D, a second exposure step was performed. The second exposure step exposed the parts of the resist film 130 corresponding to the grooves 111 in an exposure of 0.2 μC/cm² once to several times according to the positions of those parts on the X-axis perpendicular to the length of the grooves 111 to expose those parts of the resist film 130 in different total exposures, respectively.

The exposures for the positions on the X-axis were determined through simulation.

Then, the exposed resist film 130 was subjected to a developing step to form openings 131 in parts of the resist film 130 corresponding to the grooves 111 as shown in FIG. 2E. The widths of the openings 131 were dependent on the exposures in which the parts, of the resist film 130 corresponding to the grooves 111, were exposed.

Parts of the screening film (chromium film) 120 exposed in the openings 131 of the resist film 130 were removed by a dry etching step using CH₂Cl₂ gas to form openings 121 as shown in FIG. 2F.

Then, the transparent substrate 110 was subjected to a dry etching step using the screening film 120 as a mask and CF₄ gas as an etching gas to form the grooves 111 by etching parts of the surface of the transparent substrate 110 exposed in the openings 131 of the resist film 130 and the openings 121 of the screening film 120 as shown in FIG. 2G. The grooves 111 were formed in a depth of 250 nm equal to half the wavelength of light to be used for forming a diffraction grating in an optical fiber.

Then, the resist film 130 was removed by using a sulfuric acid solution heated at 70° C., and the screening film 120 was removed by using an ammonium cerium per nitrate solution in FIGS. 2H-2I. The transparent substrate 110 was cleaned by a cleaning process. The grooves 111 of 100 mm in length were arranged at pitches of 1.06 μm in a pattern 111P. The grooves 111 were formed in different widths according to the positions of the grooves 111 on the X-axis, respectively.

Thus, the phase mask 21 in the example as shown in FIG. 1 was completed.

FIG. 1B shows the distribution of the duty ratio of the pattern 111P.

A diffraction grating was formed in an optical fiber by using the phase mask 21 thus fabricated. The influence of the optical intensity of zero-order light on the optical fiber could be reduced and the side lobes in the reflection spectrum could be suppressed by duty ratio adjustment.

An exposure process for exposing the optical fiber to light to form the diffraction grating in the optical fiber could be controlled so as to reduce the zero-order term ratio.

The phase mask was capable of achieving apodization exposure in forming the diffraction grating in the optical fiber.

According to the present invention, the phase mask is capable of accurately forming a satisfactory diffraction grating in an optical fiber by a single-exposure method instead of by a double-exposure method including an exposure step using a phase mask and an apodization exposure step, or by the exposure method using a phase mask and a spatial amplitude filter disposed in front of the phase mask as shown in FIG. 3 of JP7-140311A.

1. A phase mask, for forming a diffraction grating in an object for an optical medium, including a photosensitive part by exposing the object to UV light containing diffracted light rays to cause the refractive index of the photosensitive part of the object to change by interference fringes produced by interference of diffracted light rays of different orders of diffraction, said phase mask comprising:
a transparent substrate having one surface provided with a pattern of a plurality of grooves;
wherein the pattern of the grooves has a duty ratio adjusted according to the positions of the grooves so that apodization exposure can be achieved when the object is exposed to the UV light through the phase mask.

2. The phase mask, for forming a diffraction grating, according to claim 1, wherein
the duty ratio of the pattern is adjusted by adjusting the respective widths of the grooves for apodization exposure according to the positions of the grooves.

3. A phase mask, for forming a diffraction grating in an object for an optical medium, including a photosensitive part by exposing the object to UV light containing diffracted light rays to cause the refractive index of the photosensitive part of the object to change by interference fringes produced by interference of diffracted light rays of different orders of diffraction, said phase mask comprising:
a transparent substrate having one surface provided with a pattern of a plurality of grooves;
wherein the respective depths of the grooves are adjusted according to the positions of the grooves so that apodization exposure can be achieved when the object is exposed to the UV light through the phase mask.

4. The phase mask, for forming a diffraction grating, according to claim 1 or 3, wherein
the phase mask is characterized in forming a diffraction grating in the object having a discontinuously changing period.

5. The phase mask, for forming a diffraction grating, according to claim 1 or 3, wherein
the object is used for forming an optical waveguide.

6. The phase mask, for forming a diffraction grating, according to claim 5, wherein
the object is used for forming an optical fiber.

7. A phase mask fabricating method of fabricating a phase mask, for forming a diffraction grating in an object for an optical medium, including a photosensitive part by exposing the object to UV light containing diffracted light rays to cause the refractive index of the photosensitive part of the object to change by interference fringes produced by interference of diffracted light rays of different orders of diffraction, comprising a transparent substrate having one surface provided with a pattern of a plurality of grooves, said phase mask fabricating method comprising the steps of:
preparing a transparent substrate; and
processing the transparent substrate by a photolithographic process including an exposure step for forming grooves, a pattern development step and an etching step;
wherein exposure for forming the grooves is changed during the photolithographic process such that the pattern of the grooves has a duty ratio adjusted according to the positions of the grooves so that apodization exposure can be achieved when the object is exposed to UV light through the phase mask.

8. The phase mask fabricating method according to claim 7, wherein
the photolithographic process adjusts the exposure by a multiple exposure method in forming the grooves.

9. A phase mask fabricating method of fabricating a phase mask, for forming a diffraction grating in an object for an optical medium, including a photosensitive part by exposing the object to UV light containing diffracted light rays to cause the refractive index of the photosensitive part of the object to change by interference fringes produced by interference of diffracted light rays of different orders of diffraction, comprising a transparent substrate having one surface provided with a pattern of a plurality of grooves, said phase mask fabricating method comprising the steps of:
preparing a transparent substrate; and
processing the transparent substrate by a photolithographic process including an exposure step for forming grooves, a pattern development step and an etching step;
wherein the number of times of the photolithographic process in order to adjust the respective depths of the grooves according to the positions of the grooves so that apodization exposure can be achieved when the object is exposed to the UV light through the phase mask.

10. The phase mask fabricating method according to claim 7 or 9, wherein
the exposure step in the photolithographic process is carried out by an electron lithography system or a laser lithography system.

11. The phase mask fabricating method according to claim 7 or 9, wherein
the object is used for forming an optical guide.

12. The phase mask fabricating method according to claim 11, wherein
the object is used for forming an optical fiber.

13. A diffraction grating forming method using a phase mask comprising a transparent substrate having one surface provided with a pattern of a plurality of grooves having a duty ratio adjusted according to the positions of the grooves so that apodization exposure can be achieved when an object for an optical medium, having a photosensitive part is exposed to UV light through the phase mask, said diffraction grating forming method comprising the steps of:
exposing the object to UV light containing diffracted light rays diffracted by the phase mask; and
forming a diffraction grating in the object by causing the refractive index of the photosensitive part of the object to change by interference fringes produced by interference of the diffracted light rays of different orders of diffraction.

14. A diffraction grating forming method using a phase mask having a transparent substrate having one surface provided with a pattern of a plurality of grooves respectively having depths adjusted according to the positions of the grooves so that apodization exposure can be achieved when an object for an optical medium, having a photosensitive part is exposed to the UV light through the phase mask, said diffraction grating forming method comprising the steps of:
exposing the object to UV light containing diffracted light rays diffracted by the phase mask; and
forming a diffraction grating in the object by causing the refractive index of the photosensitive part of the object to change by interference fringes produced by interference of the diffracted light rays of different orders of diffraction.
